(19) United States
(12) Patent Application Publication
(10) Pub. No.: US 2026/0101682 A1
(43) Pub. Date: Apr. 9, 2026

(54) SELECTIVE DEPOSITION METHOD OF THIN FILM AND METHOD OF MANUFACTURING SEMICONDUCTOR DEVICE

(71) Applicants: Samsung Electronics Co., Ltd, Suwon-si (KR); INCHEON NATIONAL UNIVERSITY RESEARCH & BUSINESS FOUNDATION, Incheon (KR); Hongik University Industry-Academia Cooperation Foundation, Seoul (KR)

(72) Inventors: Young Min LEE, Suwon-si (KR); Han-Bo-Ram LEE, Incheon (KR); Miso KIM, Seoul (KR); Bonggeun SHONG, Seoul (KR); JEONGYUB LEE, Suwon-si (KR); Youngchul LEEM, Suwon-si (KR); Eun-Hyoung CHO, Suwon-si (KR); Dabin KONG, Incheon (KR)

(21) Appl. No.: 19/349,960

(22) Filed: Oct. 4, 2025

(30) Foreign Application Priority Data
Oct. 4, 2024 (KR) 10-2024-0135112

(51) Int. Cl. H01L 21/285

(52) U.S. Cl. CPC H10P 14/432

(57) ABSTRACT

A selective deposition method of a thin film includes: exposing a plurality of dielectric areas including a first dielectric area and a second dielectric area, supplying a reaction inhibitor and adsorbing the reaction inhibitor onto the plurality of dielectric areas, supplying a reaction auxiliary agent, which reacts with the reaction inhibitor, to selectively remove the reaction inhibitor adsorbed on the first dielectric area, supplying a reaction precursor for forming the thin film and adsorbing the reaction precursor for forming the thin film on the first dielectric area from which the reaction inhibitor is removed, and supplying a reactant for forming the thin film, which reacts with the a reaction precursor for forming the thin film, to selectively form an atomic layer on the first dielectric area.

### CROSS-REFERENCE TO RELATED APPLICATION

This application claims priority to Korean Patent Application No. 10-2024-0135112, filed on Oct. 4, 2024, and all the benefits accruing therefrom under 35 U.S.C. § 119, the content of which in its entirety is herein incorporated by reference.

### BACKGROUND

### 1. Field

The present disclosure relates to a selective deposition method of a thin film and a method of manufacturing a semiconductor device.

### 2. Description of the Related Art

Semiconductor devices include integrated circuits, including metal oxide semiconductor field effect transistors (MOSFETs). As semiconductor devices are down-scaled, a size of the MOSFETs therein is desired to be reduced, and various structures and methods to reduce the size of the MOSFET are being studied.

### SUMMARY

An embodiment provides a selective deposition method of a thin film, which may selectively form a thin film in a desired area without a patterning process such as etching.

Another embodiment provides a method of manufacturing a semiconductor device that may simplify the process while securing electrical characteristics.

According to an embodiment, a selective deposition method of a thin film includes exposing a plurality of dielectric areas including a first dielectric area and a second dielectric area, supplying a reaction inhibitor to adsorb the reaction inhibitor onto the plurality of dielectric areas, supplying a reaction auxiliary agent, which reacts with the reaction inhibitor, to selectively remove the reaction inhibitor adsorbed on the first dielectric area, supplying a reaction precursor for forming the thin film to adsorb the reaction precursor on the first dielectric area from which the reaction inhibitor has been removed, and supplying a reactant for forming the thin film, which reacts with the reaction precursor, to selectively form an atomic layer on the first dielectric area.

In an embodiment, the first dielectric area may include a first dielectric, the second dielectric area may include a second dielectric different from the first dielectric, and the first dielectric and the second dielectric may have different activation energies to remove the reaction inhibitor by the reaction auxiliary agent.

In an embodiment, an activation energy of the first dielectric to remove the reaction inhibitor may be less than an activation energy of the second dielectric to remove the reaction inhibitor.

In an embodiment, the first dielectric and the second dielectric may each independently be an oxide or an oxynitride, or the first dielectric and the second dielectric are each independently a nitride or an oxynitride.

In an embodiment, the first dielectric and the second dielectric may each independently an oxide, a nitride, or an oxynitride, each including Ag, Mg, Cu, Zr, Zn, Hf, Cr, Al, Co, Fe, Ti, Sn, Si, Ge, Mn, W, Mo, or a combination thereof.

In an embodiment, the first dielectric may include an oxide including Ag, Mg, Cu, Zr, Zn, Hf, Cr, Al, Co, Fe, Ti, Sn, or a combination thereof or an oxynitride including Ag, Mg, Cu, Zr, Zn, Hf, Cr, Al, Co, Fe, Ti, Sn, or a combination thereof, and the second dielectric may be an oxide including Si, Ge, Mn, W, Mo, or a combination thereof or an oxynitride including Si, Ge, Mn, W, Mo, or a combination thereof.

In an embodiment, the plurality of dielectric areas may further include a third dielectric area, the third dielectric area may include a third dielectric which is different from the first dielectric and the second dielectric, and the activation energy of the third dielectric to remove the reaction inhibitor may be greater than the activation energy of the first dielectric to remove the reaction inhibitor and may be less than the activation energy of the second dielectric to remove the reaction inhibitor.

In an embodiment, the first dielectric may be an oxide including Ag, Mg, Cu, Zr, Zn, Hf, Cr, Al, Co, Fe, or a combination thereof or an oxynitride including Ag, Mg, Cu, Zr, Zn, Hf, Cr, Al, Co, Fe, or a combination thereof, the second dielectric may be an oxide including Si, Ge, Mn, W, Mo, or a combination thereof or an oxynitride including Si, Ge, Mn, W, Mo, or a combination thereof, and the third dielectric may be an oxide including Sn, Ti, or a combination thereof or an oxynitride including Sn, Ti, or a combination thereof.

In an embodiment, in the supplying of the reaction auxiliary agent, a portion of the reaction inhibitor adsorbed on the third dielectric area may be removed, and the reaction inhibitor remaining on the third dielectric area may be less than the reaction inhibitor remaining on the second dielectric area.

In an embodiment, in the supplying of the reactant, a thin film may be formed on the first dielectric area and the third dielectric area, the thin film on the first dielectric area may be formed to a first thickness, and the thin film on the third dielectric area may be formed to a second thickness thinner than the first thickness.

In an embodiment, the reaction inhibitor may include dimethylamino trimethylsilane, dimethylamino dimethylsilane, diethylamino trimethylsilane, diethylamino dimethylsilane, or a combination thereof.

In an embodiment, the reaction auxiliary agent may include H₂O, H₂O₂, NH₃, H₂, or a combination thereof.

In an embodiment, the thin film may include a conductive layer including one or more atomic layers.

In an embodiment, the conductive layer may include Cu, Al, Ti, Ta, W, Co, Mo, Ni, Ag, Au, Pt, Ir, Re, Rh, Ru, an alloy thereof, a nitride thereof, a carbide thereof, or a combination thereof.

In an embodiment, the first dielectric area and the second dielectric area may each have a three-dimensional surface, and the thin film may be selectively formed on the three-dimensional surface of the first dielectric area.

According to another embodiment, a method of manufacturing a semiconductor device includes forming a dielectric layer, and selectively depositing one or more atomic layers on the dielectric layer, where the depositing of the one or more atomic layers includes the selective deposition method of the thin film described above.

According to another embodiment, a method of manufacturing a semiconductor device includes forming a transistor channel on a substrate, forming a gate dielectric layer on the transistor channel, and forming a gate electrode on the gate dielectric layer, where the forming of the gate electrode includes the selective deposition method of the thin film described above.

According to another embodiment, a method of manufacturing a semiconductor device forming a transistor channel on a substrate, forming a gate dielectric layer on the transistor channel, and forming a gate electrode on the gate dielectric layer, where the transistor channel includes a first transistor channel and a second transistor channel which are stacked in a vertical direction with respect to a surface of the substrate, the gate electrode includes a first gate electrode and a second gate electrode which are stacked in the vertical direction with respect to the surface of the substrate and include different conductors, the first gate electrode overlaps the first transistor channel in the vertical direction, and the second gate electrode overlaps the second transistor channel in the vertical direction, and the forming of the gate electrode includes forming a conductor for the first gate electrode on the gate dielectric layer, forming a hardmask layer on the conductor for the first gate electrode, removing a portion of the hardmask layer to expose a portion of the conductor for the first gate electrode, removing an exposed portion of the conductor for the first gate electrode to form the first gate electrode and expose a portion of the gate dielectric layer, supplying a reaction inhibitor onto the exposed portion of the gate dielectric layer and the hardmask layer and adsorbing the reaction inhibitor onto an exposed portion of the gate dielectric layer and the hardmask layer, supplying a reaction auxiliary agent, which reacts with the reaction inhibitor, to selectively remove the reaction inhibitor adsorbed on the exposed portion of the gate dielectric layer, supplying a reaction precursor for a second gate electrode and adsorbing the reaction precursor for the second gate electrode on a portion of the gate dielectric layer from which the reaction inhibitor is removed, supplying a reactant for the second gate electrode, which reacts with the reactant precursor for the second gate electrode, to selectively form the second gate electrode on the gate dielectric layer, and removing the hardmask layer.

In an embodiment, the method may further include forming a conductive layer having a different work function from the second gate electrode after the removing of the hardmask layer.

In an embodiment, the gate dielectric layer may include an oxide including Ag, Mg, Cu, Zr, Zn, Hf, Cr, Al, Co, Fe, Ti, Sn, or a combination thereof or an oxynitride including Ag, Mg, Cu, Zr, Zn, Hf, Cr, Al, Co, Fe, Ti, Sn, or a combination thereof, and the hardmask layer may include an oxide including Si, Ge, Mn, W, Mo, or a combination thereof or an oxynitride including Si, Ge, Mn, W, Mo, or a combination thereof.

In embodiments of the present disclosure, a thin film may be selectively formed in a desired area among chemically similar areas without a patterning process such as etching, and the method of selectively forming the thin film may be effectively applied to three-dimensional semiconductor devices.

### BRIEF DESCRIPTION OF THE DRAWINGS

FIGS. 1 to 6 are drawings showing an example of a selective deposition method of a thin film according to an embodiment,

FIGS. 7 to 12 are drawings showing other examples of a selective deposition method of a thin film according to an embodiment,

FIG. 13 is a plan view showing an example of a semiconductor device according to an embodiment,

FIG. 14 is a cross-sectional view of the semiconductor device of FIG. 13 taken along line C-C′, and

FIGS. 15 to 24 are cross-sectional views showing an example of a method of manufacturing a single height cell of a semiconductor device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Here, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a selective deposition method of a thin film according to embodiments will be described.

A selective deposition method of a thin film according to an embodiment may be applied to selectively deposit various thin films including a conductive layer, a semiconductor layer, a dielectric layer, or a combination thereof on a desired area, and may be a bottom-up process that chemically deposits the thin film in a self-aligned manner without a patterning process such as etching.

A thin film may include one or more atomic layers. A thin film may be formed by atomic layer deposition, which utilizes chemisorption and self-saturated reactions to form monomolecular layers with a thickness of several angstroms to tens of nanometers per cycle, and the cycle may be repeated multiple times to form the thin film in a desired thickness. The atomic layer deposition may be performed by placing a substrate on which a thin film is to be deposited in an atomic layer deposition chamber and supplying the reaction inhibitor, reaction auxiliary agent, reaction precursor, and reactant described below in a gas phase.

A selective deposition method of a thin film according to an embodiment may be effectively applied to selectively deposit a thin film on a portion of areas among a plurality of areas including chemically similar materials or to deposit thin films with different thicknesses on a plurality of areas including chemically similar materials. Herein, the chemically similar materials may be a heterogeneous material, but the degree of adsorption for the materials to be adsorbed (target material) may be substantially the same as each other or a difference therebetween is not substantially large. For example, the activation energies for the adsorption reaction between the chemically similar materials and the target material may be the same as each other or a difference therebetween is small, so that a degree of adsorption of the target material for the chemically similar materials may be substantially the same as each other without selectivity for a given area.

For example, chemically similar materials may be materials belonging to a same or similar category. For example, chemically similar materials included in the plurality of areas may each be dielectrics. For example, chemically similar materials included in the plurality of areas may each be an oxide or an oxynitride. For example, chemically similar materials included in the plurality of areas may each be a nitride or an oxynitride. For example, chemically similar materials included in the plurality of areas may each be a conductor, for example, each may be a metal. For example, chemically similar materials included in the plurality of areas may each include a semiconductor, or for example, may each be a semi-metal.

An example of a selective deposition method of (for forming) a thin film according to an embodiment will hereinafter be ‘described with reference to the accompanying drawings.

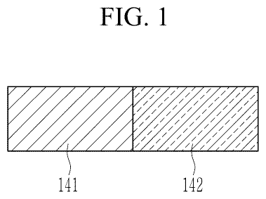

FIGS. 1 to 6 are drawings showing an example of a selective deposition method of a thin film according to an embodiment.

A selective deposition method of a thin film according to an embodiment includes exposing a plurality of dielectric areas including a first dielectric area 141 and a second dielectric area 142, supplying a reaction inhibitor 10 to adsorb the reaction inhibitor 10 onto the plurality of dielectric areas (a first dielectric area 141 and a second dielectric area 142), supplying a reaction auxiliary agent 20 configured to react with the reaction inhibitor 10 to selectively remove the reaction inhibitor 10 on a portion of the plurality of dielectric areas 141 and 142 (e.g., the first dielectric area 141), supplying a reaction precursor 30 for forming a thin film to adsorb the reaction precursor 30 on an area from which a reaction inhibitor 10 is removed, and supplying a reactant which reacts with the reaction precursor 30 for forming a thin film to selectively form an atomic layer on the portion of the plurality of dielectric areas 141 and 142 (e.g., the first dielectric area 141).

The processes may be performed in an atomic layer deposition chamber (not shown).

In an embodiment of a selective deposition method of a thin film, referring to FIG. 1, a first dielectric area 141 and a second dielectric area 142 including chemically similar materials are exposed. The first dielectric area 141 and the second dielectric area 142 may be formed on a substrate (not shown), and the substrate may be a semiconductor substrate including, for example, at least one selected from silicon, germanium, or silicon germanium, and may be, for example, a silicon wafer.

The first dielectric area 141 and the second dielectric area 142 may include different dielectrics that are chemically similar to each other, and the first dielectric area 141 may include the first dielectric and the second dielectric area 142 may include the second dielectric that is different from the first dielectric. In an embodiment, for example, the first dielectric and the second dielectric may each independently be an oxide or an oxynitride. In an embodiment, for example, the first dielectric and the second dielectric may each independently be a nitride or an oxynitride.

In an embodiment, for example, the first dielectric and the second dielectric may be different from each other and may each independently be an oxide, a nitride or an oxynitride including Ag, Mg, Cu, Zr, Zn, Hf, Cr, Al, Co, Fe, Ti, Sn, Si, Ge, Mn, W, Mo, or a combination thereof.

In an embodiment, for example, the first dielectric may be an oxide including Ag, Mg, Cu, Zr, Zn, Hf, Cr, Al, Co, Fe, Ti, Sn, or a combination thereof or an oxynitride including Ag, Mg, Cu, Zr, Zn, Hf, Cr, Al, Co, Fe, Ti, Sn, or a combination thereof, and the second dielectric may be an oxide including Si, Ge, Mn, W, Mo, or a combination thereof or an oxynitride including Si, Ge, Mn, W, Mo, or a combination thereof.

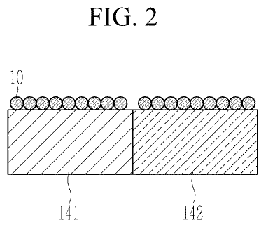

Referring to FIG. 2, in an embodiment of a selective deposition method of a thin film, a reaction inhibitor 10 is supplied onto the first dielectric area 141 and the second dielectric area 142.

The reaction inhibitor 10 may be a small molecule inhibitor (SMI), and may be, for example, a small molecule compound that may be adsorbed to functional groups (e.g., hydroxyl groups (—OH)) of the surfaces of the first dielectric area 141 and the second dielectric area 142. The reaction inhibitor 10 may be, for example, a substituted or unsubstituted aminosilane compound, for example, an alkylamino alkylsilane, and may include dimethylamino trimethyl silane, dimethylamino dimethyl silane, diethylamino trimethylsilane, diethylamino dimethyl silane, or a combination thereof, but is not limited thereto.

The reaction inhibitor 10 may chemically bind to a functional group (e.g., a hydroxyl group (—OH)) of the surface of the first dielectric area 141 and the second dielectric area 142. In an embodiment, for example, where an alkylamino alkylsilane is supplied as a reaction inhibitor 10 on a first dielectric area 141 and a second dielectric area 142 having a hydroxyl group (—OH) at the surface thereof, the hydroxyl group (—OH) and the alkylsilyl group of the first dielectric area 141 and the second dielectric area 142 are bound to form a Si—O bond, so that the reaction inhibitor 10 may be adsorbed on the first dielectric area 141 and the second dielectric area 142, and the alkylamino group (reaction byproduct) may be separated.

In an embodiment, as described above, the first dielectric included in the first dielectric area 141 and the second dielectric included in the second dielectric area 142 are chemically similar materials, and thus their activation energies for the adsorption reaction with the reaction inhibitor 10 may be the same as or similar to each other, i.e., have a small difference therebetween. Accordingly, when the reaction inhibitor 10 is supplied on the first dielectric area 141 and the second dielectric area 142, the reaction inhibitor 10 may be adsorbed to substantially the same or similar extent on the first dielectric area 141 and the second dielectric area 142.

Subsequently, purging is performed by supplying purge gas into the atomic layer deposition chamber. The purge gas may include, for example, N₂, Ne, Ar, He, or a combination (e.g., a mixture) thereof, and may be supplied at a flow rate of, for example, about 10 standard cubic centimeters per minute (sccm) to about 2000 sccm. The purging may remove impurities in the atomic layer deposition chamber by discharging unreacted materials and/or reaction byproducts of the aforementioned reaction inhibitor 10.

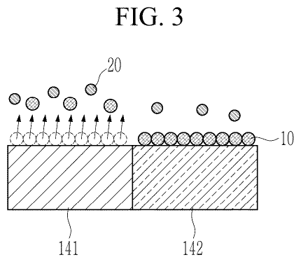

Referring to FIG. 3, in an embodiment of a selective deposition method of a thin film, a reaction auxiliary agent 20 is supplied on the reaction inhibitor 10. The reaction auxiliary agent 20 may be a material that may chemically react with the reaction inhibitor 10, and may be, for example, a material that may chemically bond with the reaction inhibitor 10, such as through hydrogen bonding. The reaction auxiliary agent 20 may include H₂O, H₂O₂, NH₃, H₂, or a combination thereof, but is not limited thereto.

The reaction auxiliary agent 20 may chemically bind with the reaction inhibitor 10 to remove or separate the reaction inhibitor 10 from the first dielectric area 141 and the second dielectric area 142. In an embodiment, for example, where the reaction inhibitor 10 is adsorbed on the surfaces of the first dielectric area 141 and the second dielectric area 142 by Si—O bonds and H₂O may be supplied as a reaction auxiliary agent 20, the reaction inhibitor 10 may be removed or separated from the first dielectric area 141 and the second dielectric area 142 by hydrolysis.

In an embodiment, the first dielectric included in the first dielectric area 141 and the second dielectric included in the second dielectric area 142 may have different activation energies (determined or calculated) to remove (or separate) the reaction inhibitor 10 by the reaction auxiliary agent 20. The activation energy to remove (or separate) the reaction inhibitor 10 may be calculated through Ab initio quantum chemistry methods considering molecular structure, etc., and the energy required to reach the transition state may be calculated, for example, through the Gaussian09 program.

In an embodiment, for example, when selectively forming a thin film on the first dielectric area 141 among the first dielectric area 141 and the second dielectric area 142, the activation energy of the first dielectric to remove the reaction inhibitor 10 from the first dielectric area 141 by the reaction auxiliary agent 20 may be smaller than the activation energy of the second dielectric to remove the reaction inhibitor 10 from the second dielectric area 142. Due to this difference in activation energy, the reaction inhibitor 10 adsorbed on the first dielectric area 141 may be removed or separated more easily than the reaction inhibitor 10 adsorbed on the second dielectric area 142, and for example, the reaction inhibitor 10 adsorbed on the first dielectric area 141 may be selectively removed or separated.

In an embodiment, for example, the difference between the activation energy of the second dielectric to remove the reaction inhibitor 10 from the second dielectric area 142 and the activation energy of the first dielectric to remove the reaction inhibitor 10 from the first dielectric area 141 may be greater than or equal to about 0.2 electronvolt (eV), or in a range from, for example, about 0.2 eV to about 2.0 eV, about 0.3 eV to about 2.0 eV, or about 0.5 eV to about 2.0 eV.

In an embodiment, for example, as illustrated in FIG. 3, the reaction inhibitor 10 adsorbed on the first dielectric area 141 may be selectively removed by the reaction auxiliary agent 20, and the reaction inhibitor 10 on the second dielectric area 142 may not be removed. By selective removal of the reaction inhibitor 10, the first dielectric area 141 may be exposed and the second dielectric area 142 may be covered by the reaction inhibitor 10.

In an embodiment, for example, where the first dielectric is HfO₂, the second dielectric is SiO₂, and the first dielectric area 141, the second dielectric area 142 are covered with a reaction inhibitor 10 derived from an alkylamino alkylsilane, and H₂O is supplied thereto as a reaction auxiliary agent 20, the activation energy (0.46 eV) of the first dielectric (HfO₂) to remove the reaction inhibitor 10 may be smaller than the activation energy (1.39 eV) of the second dielectric (SiO₂) to remove the reaction inhibitor 10, and accordingly, only the reaction inhibitor 10 derived from the alkylamino alkylsilane adsorbed on the first dielectric (HfO₂) may be selectively removed, and the reaction inhibitor 10 derived from the alkylamino alkylsilane adsorbed on the second dielectric (SiO₂) may remain.

Subsequently, purging is performed by supplying purge gas into the atomic layer deposition chamber. The purge gas may include, for example, N₂, Ne, Ar, He, or a mixture thereof, and may be supplied at a flow rate of, for example, about 10 sccm to 2000 sccm. The purging may remove impurities in the atomic layer deposition chamber by discharging unreacted materials of the aforementioned reaction auxiliary agent 20, reactants of the reaction inhibitor 10 and the reaction auxiliary agent 20, and/or reaction byproducts.

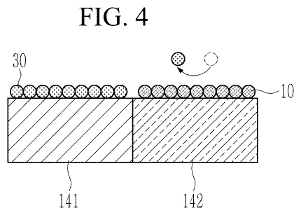

Referring to FIG. 4, in an embodiment of a selective deposition method of a thin film, a reaction precursor 30 for forming a thin film is supplied.

The reaction precursor 30 may be selectively adsorbed on the first dielectric area 141 that is not covered by the reaction inhibitor 10. The second dielectric area 142 is covered with a reaction inhibitor 10, so that adsorption of a reaction precursor 30 may be blocked by the reaction inhibitor 10.

The reaction precursor 30 may vary depending on the type of thin film 124 to be formed. In an embodiment, for example, where the thin film 124 includes a conductive layer, the reaction precursor 30 may be a precursor of a metal, a semi-metal, or an alloy thereof, capable of forming the conductive layer. The reaction precursor 30 may be, for example, a metal halide, a metal alkoxide, an organometallic precursor, or a combination thereof, where the metal may include Cu, Al, Ti, Ta, W, Co, Mo, Ni, Ag, Au, Pt, Ir, Re, Rh, Ru, or a combination thereof, but is not limited thereto.

Subsequently, purging is performed by supplying a purge gas into the atomic layer deposition chamber. The purge gas may include, for example, N₂, Ne, Ar, He, or a mixture thereof, and may be supplied at a flow rate of, for example, about 10 sccm to 2000 sccm. The purging may remove impurities in the atomic layer deposition chamber by discharging excess reaction precursor 30 and its byproducts.

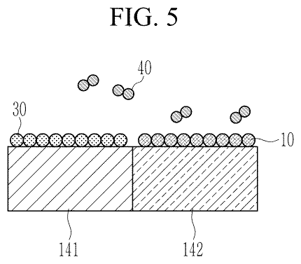

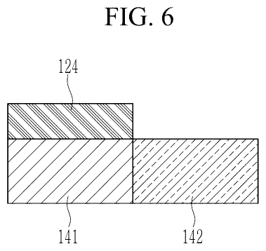

Referring to FIGS. 5 and 6, in an embodiment of a selective deposition method of a thin film, a reactant 40 for forming a thin film is supplied.

The reactant 40 may be a material that may react with the reactant precursor 30 to form a thin film 124 (e.g., a conductive layer). The reactant 40 may be, for example, a hydrogen supply material, a nitrogen supply material, and/or a carbon supply material, and may be formed into an atomic layer by reacting with the reactant precursor 30 on the first dielectric area 141. The second dielectric area 142 is covered by a reaction inhibitor 10 and no reaction precursor 30 is present, and thus no atomic layer is formed. Accordingly, the atomic layer may be selectively formed only on the first dielectric area 141.

Subsequently, purging is performed by supplying a purge gas into the atomic layer deposition chamber. The purge gas may include, for example, N₂, Ne, Ar, He, or a mixture thereof, and may be supplied at a flow rate of, for example, about 10 sccm to 2000 sccm. The purging may remove impurities within the atomic layer deposition chamber by discharging unreacted materials of the reaction precursor 30, unreacted materials of the reactant 40, and/or reaction byproducts.

The aforementioned process may be performed in one cycle to form one atomic layer (a single monomolecular layer), and by repeating multiple cycles, two or more atomic layers (a plurality of monomolecular layers) may be formed to form a thin film 124 with a desired thickness. In an embodiment, for example, the cycle may be performed 1 to 3000 times, but is not limited thereto. A thickness of the thin film 124 may be in a range from, for example, about 0.1 nanometer (nm) to about 30 nm, but is not limited thereto.

The thin film 124 may include or be defined by one or more atomic layers, and may be, for example, a conductive layer composed of one or more atomic layers. The conductive layer may include Cu, Al, Ti, Ta, W, Co, Mo, Ni, Ag, Au, Pt, Ir, Re, Rh, Ru, an alloy thereof, a nitride thereof, a carbide thereof, or a combination thereof, but is not limited thereto.

In FIGS. 1 to 6, an embodiment in which a thin film 124 is formed on one surface of the first dielectric area 141 and the second dielectric area 142 is shown, but the present disclosure is not limited thereto, and the first dielectric area 141 and the second dielectric area 142 may have three-dimensional surfaces of the first dielectric area 141 and the second dielectric area 142. Accordingly, the thin film 124 may be selectively formed on a three-dimensional surface including the upper, lower, and side surfaces of the first dielectric area 141 according to the above-described method.

As described above, the selective deposition method of a thin film according to an embodiment may selectively deposit a thin film on a portion of areas among a plurality of areas including chemically similar materials by selectively removing a reaction inhibitor 10 in a predetermined area. Accordingly, a thin film may be selectively formed in a portion of areas among a plurality of areas including chemically similar materials without a patterning process such as etching.

Hereinafter, another example of a method for selective deposition of a thin film according to an embodiment will be described.

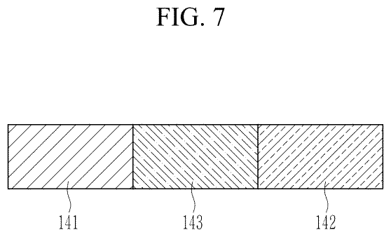

FIGS. 7 to 12 are drawings showing other examples of a selective deposition method of a thin film according to an embodiment.

Referring to FIG. 7, in another embodiment of a method for selective deposition of a thin film, the first, second, and third dielectric areas 141, 142, and 143 including chemically similar dielectrics are exposed. The first dielectric area 141, the second dielectric area 142, and the third dielectric area 143 may include chemically similar but different dielectrics, where the first dielectric area 141 may include a first dielectric, the second dielectric area 142 may include a second dielectric differing from the first dielectric, and the third dielectric area 143 may include a third dielectric differing from the first dielectric and the second dielectric. In an embodiment, for example, the first dielectric, the second dielectric, and the third dielectric are independently oxides or oxynitrides. In an embodiment, for example, the first dielectric, the second dielectric, and the third dielectric are independently nitrides or oxynitrides.

In an embodiment, for example, the first dielectric, the second dielectric, and the third dielectric may be different one from another and independently, oxides, nitrides, or oxynitrides including Ag, Mg, Cu, Zr, Zn, Hf, Cr, Al, Co, Fe, Ti, Sn, Si, Ge, Mn, W, Mo, or a combination thereof.

In an embodiment, for example, the first dielectric may be an oxide including Ag, Mg, Cu, Zr, Zn, Hf, Cr, Al, Co, Fe, or a combination thereof or an oxynitride including Ag, Mg, Cu, Zr, Zn, Hf, Cr, Al, Co, Fe, or a combination thereof, the second dielectric may be an oxide including Si, Ge, Mn, W, Mo, or a combination thereof or an oxynitride including Si, Ge, Mn, W, Mo, or a combination thereof, and the third dielectric may be an oxide including Sn, Ti, or a combination thereof or an oxynitride including Sn, Ti, or a combination thereof.

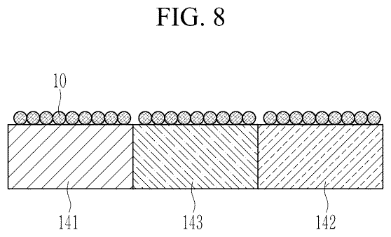

Referring to FIG. 8, in an embodiment of a method for selective deposition of a thin film, the reaction inhibitor 10 is supplied onto the first dielectric area 141, the second dielectric area 142, and the third dielectric area 143. The reaction inhibitor 10 may be a small molecule inhibitor (SMI) absorbable onto a functional group (e.g., a hydroxy group (—OH)) of the surface of the first dielectric area 141, the second dielectric area 142, and the third dielectric area 143, for example, a substituted or unsubstituted aminosilane compound, for example, alkylamino alkylsilane, for example, dimethylamino trimethylsilane, dimethylamino dimethylsilane, diethylamino trimethylsilane, diethylamino dimethylsilane, or a combination thereof.

The reaction inhibitor 10 may be absorbed on the first dielectric area 141, the second dielectric area 142, and the third dielectric area 143, where the first dielectric, the second dielectric, and the third dielectric, which are chemically similar materials, as described above, have the same or similar activation energy for an adsorption reaction with the reaction inhibitor 10. Accordingly, the reaction inhibitor 10 may be adsorbed to substantially the same or similar extent on the first dielectric area 141, the second dielectric area 142, and the third dielectric area 143.

Subsequently, purging is performed by supplying a purge gas into the atomic layer deposition chamber

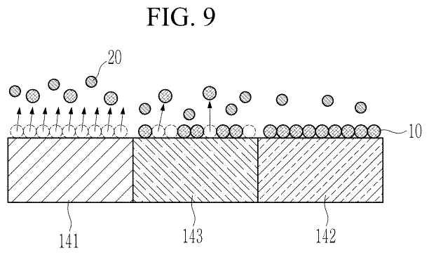

In an embodiment of a method for selective deposition of a thin film, referring to FIG. 9, the reaction auxiliary agent 20 configured to react with the reaction inhibitor 10 may be supplied onto the reaction inhibitor 10. The reaction auxiliary agent 20 may include H₂O, H₂O₂, NH₃, H₂, or a combination thereof, but is not limited thereto.

The reaction auxiliary agent 20 is chemically bonded with the reaction inhibitor 10 to remove or separate the reaction inhibitor 10 from the first dielectric area 141, the second dielectric area 142, and the third dielectric area 143. Herein, the first dielectric, the second dielectric, and the third dielectric may have different activation energies to remove (or separate) the reaction inhibitor 10 by the reaction auxiliary agent 20, for example, the activation energy of the third dielectric for removing the reaction inhibitor 10 may be larger than that of the first dielectric for removing the reaction inhibitor 10 but smaller than that of the second dielectric for removing the reaction inhibitor 10.

Such an activation energy difference may differently remove the reaction inhibitor 10 absorbed on the first dielectric area 141, the second dielectric area 142, and the third dielectric area 143, for example, the reaction inhibitor 10 absorbed on the first dielectric area 141 may be most removed, while the reaction inhibitor 10 absorbed on the second dielectric area 142 may be least or not removed, but the reaction inhibitor 10 absorbed on the third dielectric area 143 may be partially removed. Accordingly, the reaction inhibitor remaining on the third dielectric area 143 may be larger than that remaining on the first dielectric area 141 but smaller than that remaining on the second dielectric area 142.

In an embodiment, for example, the activation energy difference among the first dielectric, the second dielectric, and the third dielectric for adjusting a degree of removing the reaction inhibitor 10 may each be a greater than or equal to about 0.1 eV, or in a range from, for example, about 0.1 eV to about 2.0 eV, about 0.2 eV to about 2.0 eV, or about 0.3 eV to about 2.0 eV.

In an embodiment, for example, as shown in FIG. 9, the reaction inhibitor 10 adsorbed on the first dielectric area 141 may be removed by the reaction auxiliary agent 20, and a portion of the reaction inhibitor 10 adsorbed on the third dielectric area 143 may be removed by the reaction auxiliary agent 20, but the reaction inhibitor 10 adsorbed on the second dielectric area 142 may not be substantially removed. Such a selective removal of the reaction inhibitor 10 may expose the first dielectric area 141 and a portion of the third dielectric area 143 with the rest of the third dielectric area 143 still covered with the reaction inhibitor 10, while the second dielectric area 142 may be covered with the reaction inhibitor 10.

In an embodiment, for example, where the first dielectric is Al₂O₃, the second dielectric is SiO₂, and the third dielectric is TiO₂, the first dielectric area 141, the second dielectric area 142, and the third dielectric area 143 are covered with the reaction inhibitor 10 derived from alkylamino alkylsilane, and H₂O is supplied thereto as the reaction auxiliary agent 20, activation energy for removing the reaction inhibitor 10 by H₂O may be about 0.31 eV for the first dielectric (Al₂O₃), about 0.72 eV for the third dielectric TiO₂, and about 1.39 eV for the second dielectric (SiO₂), and accordingly, the reaction inhibitor 10 adsorbed onto the first dielectric (Al₂O₃) may be relatively easily removed, and a portion of the reaction inhibitor 10 adsorbed onto third dielectric TiO₂ may be removed, but the reaction inhibitor 10 adsorbed onto the second dielectric SiO₂ may substantially remain as it is.

Subsequently, purging is performed by supplying a purge gas into the atomic layer deposition chamber.

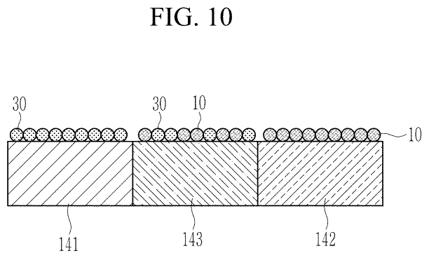

In an embodiment of a method for selective deposition of a thin film, referring to FIG. 10, the reaction precursor 30 for forming a thin film is supplied.

The reaction precursor 30 may be adsorbed onto the entire surface of the first dielectric area 141, which is not covered with the reaction inhibitor 10, and partially onto the third dielectric area 143 partially covered with the reaction inhibitor 10. The second dielectric area 142 is covered with a reaction inhibitor 10, so that adsorption of a reaction precursor 30 may be blocked.

Subsequently, purging is performed by supplying a purge gas into the atomic layer deposition chamber.

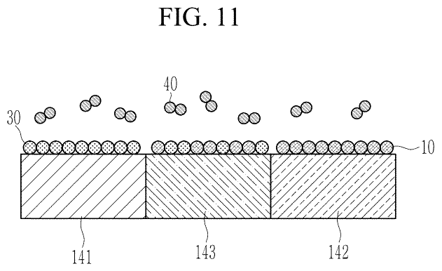

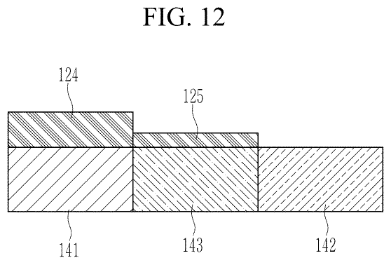

Then, referring to FIGS. 11 and 12, in an embodiment of a method for selective deposition of a thin film, the reactant 40 for forming a thin film is supplied. The reactant 40 may react with the reaction precursor 30 on the first dielectric area 141 to form an atomic layer and the reactant 40 may react with the reaction precursor 30 on the third dielectric area 143 to form an atomic layer which is thinner than the atomic layer formed on the first dielectric area 141. Since the second dielectric area 142 is covered with the reaction inhibitor 10 and has no reaction precursor 30 thereon, an atomic layer may not be formed.

Subsequently, purging is performed by supplying a purge gas into the atomic layer deposition chamber.

The above process as one cycle may proceed to form one atomic layer (a single monomolecular layer), and two or more cycles may be repeated to form two or more atomic layers (a plurality of monomolecular layers) to form a thin film 124 with a first thickness on the first dielectric area 141 and a thin film 125 with a thinner thickness than that of the first film on the third dielectric area 143. In an embodiment, for example, the cycle may be performed 1 to 3000 times, but is not limited thereto. Each thickness of thin films 124 and 125 may be in a range from, for example, about 0.1 nm to about 30 nm, but is not limited thereto.

The thin films 124 and 125 may consist of two or more atomic layers, for example, include a conductive layer composed of one or more atomic layers. The conductive layer may include Cu, Al, Ti, Ta, W, Co, Mo, Ni, Ag, Au, Pt, Ir, Re, Rh, Ru, an alloy thereof, a nitride thereof, a carbide thereof, or a combination thereof, but is not limited thereto.

In FIGS. 7 to 12, an embodiment of selectively forming the thin films 124 and 125 on each one surface of the first dielectric area 141, the second dielectric area 142, and the third dielectric area 143 is shown, but the present disclosure is not limited thereto, but the first dielectric area 141, the second dielectric area 142, and the third dielectric area 143 may have a three-dimensional surface. Accordingly, the thin film 124 with the first thickness may be formed on the three-dimensional surface including the upper, lower, and side surfaces of the first dielectric area 141 according to the above method, and the thin film 125 with the second thickness may be formed on the three-dimensional surface including the upper, lower, and side surfaces of the third dielectric area 143.

As described above, the selective deposition method of a thin film according to an embodiment may selectively deposit a thin film on a portion of areas among a plurality of areas including chemically similar materials by selectively removing the reaction inhibitor 10 in predetermined areas. Accordingly, a thin film may be selectively formed in a portion of areas among a plurality of areas including chemically similar materials without a patterning process such as etching.

As described above, the selective deposition method of a thin film according to an embodiment may selectively deposit a thin film with a different thickness depending on a plurality of areas including chemically similar materials by adjusting a degree of removing the reaction inhibitor 10. Accordingly, a thin film with a desired thickness may be selectively formed without a patterning process such as etching in a portion of areas among the plurality of areas including chemically similar materials.

Embodiments of the method described above may be applied to selectively form a thin film of a semiconductor device in a predetermined area, for example, selectively form an electrode or a wire in the predetermined area. The semiconductor device may be, for example, a three-dimensional semiconductor device.

Hereinafter, an example of a semiconductor device according to an embodiment is described with reference to the drawing.

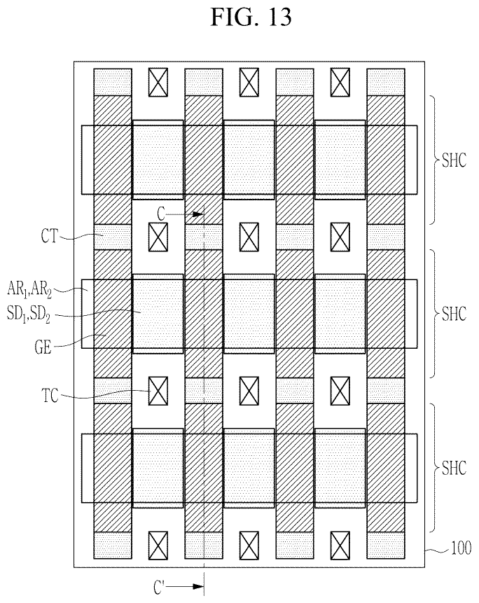

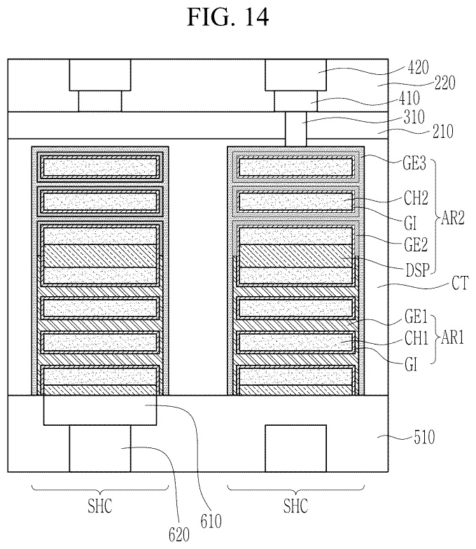

FIG. 13 is a plan view showing an example of a semiconductor device according to an embodiment, and FIG. 14 is a cross-sectional view of the semiconductor device of FIG. 13 taken along line C-C′.

Referring to FIGS. 13 and 14, the semiconductor device according to an embodiment may be a three-dimensional semiconductor device and include a plurality of single height cells SHC arranged at a predetermined interval on the substrate 100. In an embodiment, for example, the single height cells SHC may be a logic cell that constitutes a logic circuit.

The substrate 100 may be a semiconductor substrate including, for example, silicon, germanium, silicon germanium, or a combination thereof. The substrate 100 may include an insulation part including a silicon-based insulating material (e.g., silicon oxide and/or silicon nitride). The single height cells SHC may be defined by a shallow trench isolation layer, which may be provided in the substrate. The shallow trench isolation layer may include, for example, silicon oxide, silicon nitride, and/or silicon oxynitride.

Each of the single height cells SHC includes a first active area AR1 and a second active area AR2 which are stacked vertically to the surface of the substrate 100. Either one of the first active area AR1 and the second active area AR2 may be a P-channel metal oxide semiconductor field effect transistor (PMOSFET) area, and the other of the first active area AR1 and the second active area AR2 may be an N-channel metal oxide semiconductor field effect transistor (NMOSFET) area. In this way, a stacked structure of PMOSFET and NMOSFET may configure the three-dimensional stacked transistor. The first active area AR1 may be provided for a bottom tier of front-end-of-line (FEOL), and the second active area AR2 may be provided for a top tier of FEOL.

The first active area AR1 includes a plurality of first transistor channel CH1, a plurality of first sources/drains SD1, and a plurality of first gate electrodes GE1. The plurality of first transistor channels CH1 may be disposed between a pair of first source/drain SD1 and electrically connected to the first source/drain SD1. The plurality of first transistor channel CH1 may be overlapped with a first gate electrodes GE1 with a gate dielectric layer GI disposed therebetween.

The plurality of first transistor channels CH1 may be stacked to be spaced apart at a predetermined interval, where each of the first transistor channels may include silicon (Si), germanium (Ge), silicon germanium (SiGe), or a combination thereof. The plurality of first transistor channels CH1 may include, for example, crystalline silicon, for example, a silicon nanosheet.

Each of the first transistor channels CH1 may be surrounded with the gate dielectric layer GI. The gate dielectric layer GI may include a high-k material, for example, an oxide or oxynitride, including Ag, Mg, Cu, Zr, Zn, Hf, Cr, Al, Co, Fe, Ti, Sn, Si, Ge, Mn, W, Mo, or a combination thereof, for example, Ag₂O, MgO, CuO, ZrO₂, ZnO, HfO₂, Cr₂O₃, Al₂O₃, Co₃O₄, Fe₂O₃, TiO₂, SiO₂, SnO₂, GeO₂, MnO₂, WO₃, MoO₃, or a combination thereof, but is not limited thereto.

The plurality of first sources/drains SD1 may include silicon (Si), germanium (Ge), silicon germanium (SiGe), or a combination thereof, which is doped with impurities, where the impurities may be n-type impurities or p-type impurities. The plurality of first sources/drains SD1 may be, for example, epitaxial layers formed by selective epitaxial growth.

The plurality of first gate electrodes GE1 may be respectively positioned between the plurality of first transistor channels CH1 and furthermore, three-dimensionally surround the upper, lower, and side surfaces of each of the first transistor channels CH1 with the gate dielectric layer GI disposed therebetween. The plurality of first gate electrodes GE1 may include Cu, Al, Ti, Ta, W, Co, Mo, Ni, Ag, Au, Pt, Ir, Re, Rh, Ru, an alloy thereof, a nitride thereof, a carbide thereof, or a combination thereof, but is not limited thereto.

Under the first active area AR1, an interlayer insulation layer 510, a lower via 610, and a wire 620 are formed. The wire 620 may include (or be defined by) one or more metal layers and constitute FEOL.

The second active area AR2 may be stacked on the first active area AR1 and include a plurality of second transistor channels CH2, a plurality of second sources/drains SD2, and a plurality of second gate electrodes GE2. The plurality of second transistor channels CH2 may be disposed between each pair of second sources/drains SD2 and electrically connected to the second sources/drains SD2. Each of the second transistor channels CH2 may be surrounded with the gate dielectric layer GI, and the second gate electrode GE2 is positioned on the upper, lower, and side surfaces of each of the second transistor channel CH2 with the gate dielectric layer GI disposed therebetween to three-dimensionally surround each of the second transistor channels CH2. The plurality of second transistor channels CH2, the plurality of second sources/drains SD2, and the plurality of second gate electrodes GE2 may be equally described, as the first transistor channels CH1, the first sources/drains SD1, and the first gate electrodes GE1 are described above.

Between the first transistor channel CH1 of the first active area AR1 and the second transistor channel CH2 of the second active area AR2, a dummy channel pattern DSP is disposed. The dummy channel pattern DSP may include a semiconductor material such as silicon (Si), germanium (Ge), silicon germanium (SiGe), or a combination thereof or a silicon-based insulating material such as a silicon oxide film or a silicon nitride film. The dummy channel pattern DSP may not be electrically connected to the first sources/drains SD1 and the second sources/drains SD2.

On the second active area AR2, interlayer insulation layers 210 and 220, a gate contact 310, an upper via 410, and a wire 420 are formed. The gate contact 310 may electrically connect the gate electrode GE2 and the upper via 410/the wire 420 through the interlayer insulation layer 210. The wire 420 may include one or more metal layers and constitute back-end-of-line (BEOL).

A cutting pattern CT is formed between the adjacent gate electrodes GE1 in a parallel direction to the surface of the substrate 100. The cutting pattern CT may separate the adjacent gate electrodes GE1 and include, for example, silicon oxide, silicon nitride, silicon oxynitride, or a combination thereof.

Between the adjacent single height cells SHC, a through-hole conductive pattern TC is disposed. The through-hole conductive pattern TC may electrically connect the wire 420 on the front surface of the substrate 100 and a metal layer (not shown) on the rear surface of the substrate 100.

Referring to the drawing below, an example of a method of manufacturing a single height cell SHC of a semiconductor device is illustrated.

The method of forming the single height cell SHC of a semiconductor device includes selectively forming a thin film (e.g., conductive layer) on a plurality of dielectrics including chemically similar materials, where this selective formation of the thin film may include the above selective deposition method of a thin film.

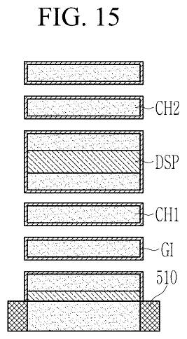

FIGS. 15 to 24 are cross-sectional views showing an example of a method of manufacturing a single height cell SHC of a semiconductor device. FIGS. 15 to 24 are drawings for illustrating the selective deposition method of a thin film, and some components unrelated hereto may be schematically illustrated or omitted in the drawings.

Referring to FIG. 15, in an embodiment of a method of manufacturing a single height cell SHC, the plurality of transistor channels CH1 and CH2 and the dummy channel pattern DSP are formed to be vertically disposed to the surface of the substrate 100. Subsequently, the gate dielectric layer GI is formed to three-dimensionally surround the plurality of transistor channels CH1 and CH2 and the dummy channel pattern DSP. The gate dielectric layer GI may include, for example, an oxide or oxynitride including Ag, Mg, Cu, Zr, Zn, Hf, Cr, Al, Co, Fe, Ti, Sn, or a combination thereof and may be formed, for example, through atomic layer deposition (ALD).

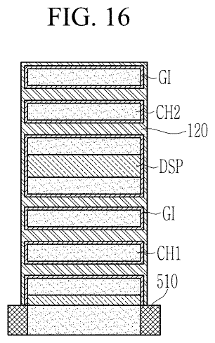

Referring to FIG. 16, in such an embodiment, a conductor 120 for the first gate electrode GE1 is formed to cover the gate dielectric layer GI. The conductor 120 for the first gate electrode GE1 may include Cu, Al, Ti, Ta, W, Co, Mo, Ni, Ag, Au, Pt, Ir, Re, Rh, Ru, an alloy thereof, a nitride thereof, a carbide thereof, or a combination thereof, but is not limited thereto. The conductor 120 for the first gate electrode GE1 may be formed between the adjacent transistor channels CH1 and CH2 and between each of the transistor channels CH1 and CH2 and the dummy channel pattern DSP and thus entirely surround the gate dielectric layer GI. The conductor 120 for the first gate electrode GE1 between the adjacent first transistor channels CH1 may be the first gate electrode GE1 on the first active area AR1.

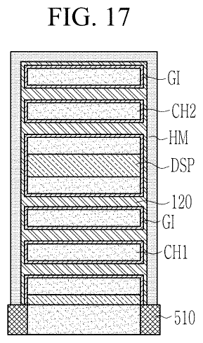

Referring to FIG. 17, in such an embodiment, on the conductor 120 for the first gate electrode GE1, a hardmask layer HM is formed. The hardmask layer HM may include a dielectric, for example, an oxide or oxynitride including Si, Ge, Mn, W, Mo, or a combination thereof.

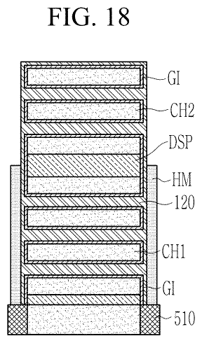

Referring to FIG. 18, in such an embodiment, a portion of the hardmask layer HM may be removed to expose a region corresponding to the second active area AR2.

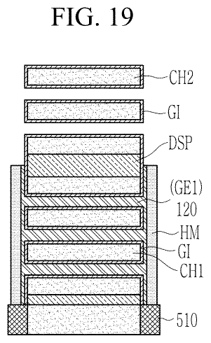

Referring to FIG. 19, in such an embodiment, the portion of conductor 120 for the first gate electrode GE1 exposed by the hardmask layer HM may be removed to form the first gate electrode GE1 and expose the gate dielectric layer GI of the second active area AR2. The removal of a portion of the conductor 120 for the first gate electrode GE1 may be performed, for example, by wet etching. This removal of the exposed portion of the conductor 120 for the first gate electrode GE1 may expose the hardmask layer HM and the gate dielectric layer GI including different dielectrics. Herein, the gate dielectric layer GI may correspond to the first dielectric area in the above-mentioned selective deposition method of a thin film, and the hardmask layer HM may correspond to the second dielectric area.

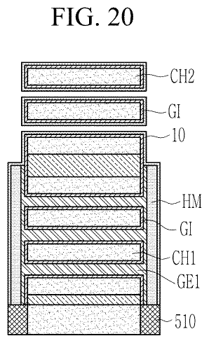

Referring to FIG. 20, in such an embodiment, the reaction inhibitor 10 may be absorbed onto the hardmask layer HM and the gate dielectric layer GI. The reaction inhibitor 10 is the same as that described above and may be substantially equally or similarly adsorbed on the hardmask layer HM and the gate dielectric layer GI including chemically similar materials, that is, dielectrics.

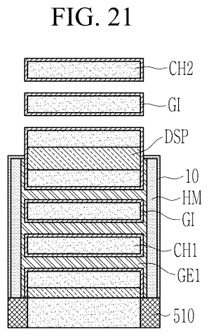

Referring to FIG. 21, in such an embodiment, a reaction auxiliary agent (not shown) which reacts with the reaction inhibitor 10 may be supplied to selectively remove the reaction inhibitor 10 adsorbed onto the exposed portion of the gate dielectric layer GI. As described above, the removal of the reaction inhibitor 10 adsorbed on the hardmask layer HM and the gate dielectric layer GI by the reaction auxiliary agent may require different activation energy, for example, the activation energy for removing the reaction inhibitor 10 from the gate dielectric layer GI may be smaller than that for removing the reaction inhibitor 10 from the hardmask layer HM. Such an activation energy difference may selectively remove the reaction inhibitor 10 adsorbed on the gate dielectric layer GI and selectively expose the gate dielectric layer GI.

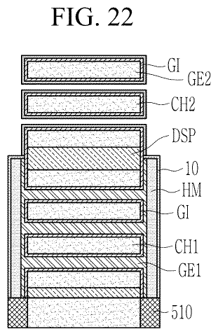

Referring to FIG. 22, in such an embodiment, a reaction precursor for the second gate electrode GE2 may be adsorbed on the exposed portion of the gate dielectric layer GI, and a reactant for the second gate electrode GE2 configured to react with the reaction precursor for the second gate electrode GE2 may be supplied thereto to selectively form the second gate electrode GE2 on the second gate dielectric layer GI. The second gate electrode GE2 may include a different conductor from that of the first gate electrode GE1. The reaction precursor for the second gate electrode GE2 may be, for example, metal halide, metal alkoxide, an organic metal precursor, or a combination thereof, where the metal may include Cu, Al, Ti, Ta, W, Co, Mo, Ni, Ag, Au, Pt, Ir, Re, Rh, Ru, or a combination thereof, and the reactant for the second gate electrode GE2 may be a material capable of forming the second gate electrode GE2 by reacting with the reaction precursor for the second gate electrode GE2. The second gate electrode GE2 may be selectively deposed on the exposed portion of the gate dielectric layer GI and selectively on the three-dimensional surface of the gate dielectric layer GI.

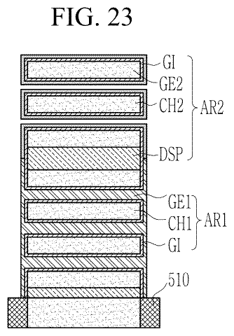

Referring to FIG. 23, in such an embodiment, the hardmask layer may be removed to form the first active area AR1 and the second active area AR2 vertically stacked.

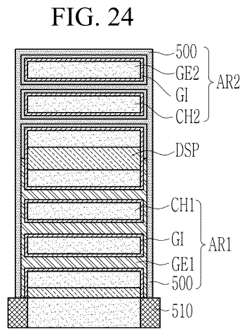

Referring to FIG. 24, in such an embodiment, on the first active area AR1 and the second active area AR2, a metal layer 500 with a different work function from those of the first gate electrode GE1 and the second gate electrode GE2 may be formed. The metal layer 500 may be respectively connected to the first gate electrode GE1 and the second gate electrode GE2, and the additional formation of the metal layer 500 may form the first gate electrode GE1 and the second gate electrode GE2 as dual metal gate electrodes with different work functions. Such dual metal gate electrodes may effectively control a threshold voltage in the three-dimensional semiconductor device with a narrow gap between the adjacent transistor channels CH1 and CH2.

In this way, in the three-dimensional semiconductor device in which transistor channels are stacked in a vertical direction, the reaction inhibitor 10 may be selectively removed, or a removal degree thereof may be controlled to selectively form a thin film (e.g., gate electrode) in a portion of areas (e.g., gate insulation layer GI) among a plurality of areas including chemically similar materials (e.g., gate insulation layer GI and hardmask layer HM). Accordingly, the upper layer may be selectively formed in a portion of areas among the plurality of areas including chemically similar materials without a complex process.

Hereinafter, embodiments of the present disclosure will be described in greater detail with reference to examples. However, these examples are merely exemplary, and the scope of the invention is not limited thereto.

### [Calculation of Activation Energy for Adsorption]

Activation energy (Eₐ₁), which may be used to determine an adsorption degree of dimethylamino trimethylsilane on the SiO₂ and HfO₂ surfaces, is calculated. The activation energy (Eₐ₁) for adsorption is obtained by calculating energy required to reach a transition state through Gaussian09 program.

The results are shown in Table 1.

TABLE 1

| | Eₐ₁ (eV) |
|---|---|
| SiO₂ | 0.81 |
| HfO₂ | 0.82 |

Referring to Table 1, since the activation energy (Eₐ₁) for adsorbing the dimethylamino trimethylsilane on the chemically similar SiO₂ and HfO₂ surfaces has an extremely small difference, the dimethylamino trimethylsilane is expected to be adsorbed substantially equally or similarly on the SiO₂ and HfO₂ surfaces.

### [Calculation of Activation Energy for Removal of Adsorption Material]

When H₂O (reaction auxiliary agent) is supplied for hydrolysis of dimethylamino trimethylsilane moieties adsorbed on the surface of various dielectrics, activation energy (Eₐ₂) used to determine a degree of removing the dimethylamino trimethylsilane moieties is calculated. The activation energy (Eₐ₂) for removing the adsorption material is calculated as energy required to reach a transition state through Gaussian09 program.

The results are shown in Table 2.

TABLE 2

| | Eₐ₂ (eV) |
|---|---|
| SiO₂ | 1.39 |
| GeO₂ | 1.07 |
| TiO₂ | 0.72 |
| SnO₂ | 0.58 |
| ZrO₂ | 0.47 |
| HfO₂ | 0.46 |
| Al₂O₃ | 0.31 |

Referring to Table 2, it is confirmed that the activation energy (Eₐ₂) for removing the adsorption material is different among chemically similar materials (dielectrics). Accordingly, it may be expected that the adsorption material may be selectively removed from the surfaces of the chemically similar materials, or a removal degree thereof may be controlled.

### EXAMPLE

A silicon substrate on which a 50 nm-thick SiO₂ (SiO₂ area) and a 50 nm-thick HfO₂ (HfO₂ area) are deposited, is placed in an atomic layer deposition chamber. Subsequently, dimethylamino trimethylsilane (DMATMS, a reaction inhibitor) is injected at a flow rate of 100 sccm for 10 seconds into the deposition chamber under a pressure of 3 Torr. Then, nitrogen gas (N₂, 99.999%) is supplied at a flow rate of 100 sccm for 20 seconds to the atomic layer deposition chamber to purge. Water (H₂O, reaction auxiliary agent) is injected at a flow rate of 300 sccm for 30 seconds into the deposition chamber under a pressure of 0.5 Torr and then purging is performed by supplying nitrogen gas under the same conditions. Subsequently, tricarbonyl trimethylenemethane ruthenium (Tanaka Kikinzoku Kogyo K.K., Japan) is injected at a flow rate of 200 sccm for 7 seconds into the deposition chamber under a pressure of 10 Torr and then, purging is performed by supplying nitrogen gas. Then, H₂ is injected at a flow rate of 300 sccm for 15 seconds into the deposition chamber under a pressure of 10 Torr, and then purging is performed by supplying nitrogen gas to deposit a ruthenium (Ru) layer on the silicon substrate. This aforementioned process as one cycle is 100 cycles repeated.

### Reference Example 1

A silicon substrate on which a 50 nm-thick SiO₂ (SiO₂ area) and a 50 nm-thick HfO₂ (HfO₂ area) are deposited is placed in an atomic layer deposition chamber. Subsequently, tricarbonyl trimethylenemethane ruthenium is injected thereinto at a flow rate of 200 sccm for 7 seconds under a deposition chamber pressure of 10 Torr and then, purged with nitrogen gas. Then, H₂ is injected thereinto at a flow rate of 300 sccm for 15 seconds under a deposition chamber pressure of 10 Torr and then, purged with nitrogen gas to deposit a ruthenium (Ru) layer on the silicon substrate. The aforementioned process as 1 cycle is 100 cycles repeated.

### Reference Example 2

A silicon substrate on which a 50 nm-thick SiO₂ (SiO₂ area) and a 50 nm-thick HfO₂ (HfO₂ area) are deposited, is placed in an atomic layer deposition chamber. Subsequently, dimethylamino trimethylsilane (DMATMS, a reaction inhibitor) is injected at a flow rate of 100 sccm for 10 seconds into the deposition chamber under a pressure of 3 Torr. Then, nitrogen gas (N₂, 99.999%) is supplied at a flow rate of 100 sccm flow rate for 20 seconds to the atomic layer deposition chamber to purge. Subsequently, tricarbonyl trimethylenemethane ruthenium (Tanaka Kikinzoku Kogyo K.K., Japan) is injected at a flow rate of 200 sccm for 7 seconds into the deposition chamber under a pressure of 10 Torr, and then, purging is performed by using nitrogen gas. Then, H₂ is injected at a flow rate of 300 sccm for 15 seconds into the deposition chamber under a pressure of 10 Torr, and purging is performed by supplying nitrogen gas to deposit a ruthenium (Ru) layer on the silicon substrate. This aforementioned process as one cycle is 100 cycles repeated.

### [Evaluation]

The ruthenium (Ru) layer in the SiO₂ and HfO₂ areas on the silicon substrate is evaluated with respect to a thickness.

The results are shown in Table 3.

TABLE 3

| | Reference | Reference | | |
|---|---|---|---|---|
| | Example 1 | Example 2 | Example | |
| Thickness of Ru layer on | 20 nm | 0 nm | 5 | nm |
| SiO₂ area | | (no growth) | | |
| Thickness of Ru layer on | 13 nm | 0 nm | 10 | nm |
| HfO₂ area | | (no growth) | | |

Referring to Table 3, the ruthenium (Ru) layer according to Reference Example 1 is formed to be thicker on the SiO₂ area than the HfO₂ area, but the ruthenium (Ru) layer according to Reference Example 2 is not formed on both the SiO₂ area and the HfO₂ area. Accordingly, in Reference Example 2, it is confirmed that the reaction inhibitor may effectively block deposition of the reaction precursor (Ru precursor) on both the SiO₂ area and the HfO₂ area. On the other hand, the ruthenium (Ru) layer according to Example is deposited to be 5 nm thick on the SiO₂ area but 10 nm thick on the HfO₂ area, that is, to be much thicker on the HfO₂ area than on the SiO₂ area unlike the ruthenium (Ru) layer according to Reference Example 1.

Accordingly, it may be expected that a reaction inhibitor may be selectively removed by a reaction auxiliary agent to selectively deposit a film among the chemically similar areas or form the film to have each desired thickness on the chemically similar areas. For example, referring to the results of Table 3, if the ruthenium (Ru) layer is deposited to be 5 nm thick on the HfO₂ area by changing deposition conditions, the ruthenium (Ru) layer may not be substantially deposited on the SiO2 area, which may make it possible to selectively deposit the ruthenium (Ru) layer between SiO2 area and HfO2 area.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A selective deposition method of a thin film, the selective deposition method comprising:
exposing a plurality of dielectric areas including a first dielectric area and a second dielectric area;
supplying a reaction inhibitor to adsorb the reaction inhibitor onto the plurality of dielectric areas;
supplying a reaction auxiliary agent, which reacts with the reaction inhibitor, to selectively remove the reaction inhibitor adsorbed on the first dielectric area;
supplying a reaction precursor for forming the thin film to adsorb the reaction precursor on the first dielectric area from which the reaction inhibitor is removed; and
supplying a reactant for forming the thin film, which reacts with the reaction precursor, to selectively form an atomic layer on the first dielectric area.

2. The selective deposition method of claim 1, wherein
the first dielectric area comprises a first dielectric,
the second dielectric area comprises a second dielectric different from the first dielectric, and
the first dielectric and the second dielectric have different activation energies to remove the reaction inhibitor by the reaction auxiliary agent.

3. The selective deposition method of claim 2, wherein an activation energy of the first dielectric to remove the reaction inhibitor is less than an activation energy of the second dielectric to remove the reaction inhibitor.

4. The selective deposition method of claim 2, wherein
the first dielectric and the second dielectric are each independently an oxide or an oxynitride, or
the first dielectric and the second dielectric are each independently a nitride or an oxynitride.

5. The selective deposition method of claim 4, wherein the first dielectric and the second dielectric are each independently an oxide, a nitride, or an oxynitride, each including Ag, Mg, Cu, Zr, Zn, Hf, Cr, Al, Co, Fe, Ti, Sn, Si, Ge, Mn, W, Mo, or a combination thereof.

6. The selective deposition method of claim 5, wherein
the first dielectric is an oxide including Ag, Mg, Cu, Zr, Zn, Hf, Cr, Al, Co, Fe, Ti, Sn, or a combination thereof or an oxynitride including Ag, Mg, Cu, Zr, Zn, Hf, Cr, Al, Co, Fe, Ti, Sn or a combination thereof, and
the second dielectric is an oxide including Si, Ge, Mn, W, Mo, or a combination thereof or an oxynitride including Si, Ge, Mn, W, Mo, or a combination thereof.

7. The selective deposition method of claim 2, wherein
the plurality of dielectric areas further comprise a third dielectric area,
the third dielectric area comprises a third dielectric which is different from the first dielectric and the second dielectric, and
an activation energy of the third dielectric to remove the reaction inhibitor is greater than an activation energy of the first dielectric to remove the reaction inhibitor and is less than an activation energy of the second dielectric to remove the reaction inhibitor.

8. The selective deposition method of claim 7, wherein
the first dielectric is an oxide including Ag, Mg, Cu, Zr, Zn, Hf, Cr, Al, Co, Fe, or a combination thereof or an oxynitride including Ag, Mg, Cu, Zr, Zn, Hf, Cr, Al, Co, Fe, or a combination thereof,
the second dielectric is an oxide including Si, Ge, Mn, W, Mo, or a combination thereof or an oxynitride including Si, Ge, Mn, W, Mo, or a combination thereof, and
the third dielectric is an oxide Sn, Ti, or a combination thereof or an oxynitride including Sn, Ti, or a combination thereof.

9. The selective deposition method of claim 7, wherein
in the supplying of the reaction auxiliary agent, a portion of the reaction inhibitor adsorbed on the third dielectric area is removed, and
the reaction inhibitor remaining on the third dielectric area is less than the reaction inhibitor remaining on the second dielectric area.

10. The selective deposition method of claim 7, wherein
in the supplying of the reactant, the thin film is formed on the first dielectric area and the third dielectric area,
the thin film on the first dielectric area is formed to have a first thickness, and
the thin film on the third dielectric area is formed to have a second thickness thinner than the first thickness.

11. The selective deposition method of claim 1, wherein the reaction inhibitor comprises dimethylamino trimethylsilane, dimethylamino dimethylsilane, diethylamino trimethylsilane, diethylamino dimethylsilane, or a combination thereof.

12. The selective deposition method of claim 1, wherein the reaction auxiliary agent comprises H₂O, H₂O₂, NH₃, H₂, or a combination thereof.

13. The selective deposition method of claim 1, wherein the thin film comprises a conductive layer including one or more atomic layers.

14. The selective deposition method of claim 13, wherein the conductive layer comprises Cu, Al, Ti, Ta, W, Co, Mo, Ni, Ag, Au, Pt, Ir, Re, Rh, Ru, an alloy thereof, a nitride thereof, a carbide thereof, or a combination thereof.

15. The selective deposition method of claim 1, wherein
the first dielectric area and the second dielectric area have a three-dimensional surface, respectively, and
the thin film is selectively formed on the three-dimensional surface of the first dielectric area.

16. A method for manufacturing a semiconductor device, the method comprising:
forming a dielectric layer; and
selectively depositing one or more atomic layers on the dielectric layer,
wherein the depositing of the one or more atomic layers comprises the selective deposition method of the thin film of claim 1.

17. A method for manufacturing a semiconductor device, the method comprising:
forming a transistor channel on a substrate;
forming a gate dielectric layer on the transistor channel; and
forming a gate electrode on the gate dielectric layer,
wherein the forming of the gate electrode comprises the selective deposition method of the thin film of claim 1.

18. A method of manufacturing a semiconductor device, the method comprising:
forming a transistor channel on a substrate;
forming a gate dielectric layer on the transistor channel; and
forming a gate electrode on the gate dielectric layer,
wherein the transistor channel comprises a first transistor channel and a second transistor channel which are stacked in a vertical direction with respect to a surface of the substrate,
the gate electrode comprises a first gate electrode and a second gate electrode which are stacked in the vertical direction with respect to the surface of the substrate and comprise different conductors,
the first gate electrode overlaps the first transistor channel in the vertical direction, and the second gate electrode overlaps the second transistor channel in the vertical direction, and
the forming of the gate electrode comprises
forming a conductor for the first gate electrode on the gate dielectric layer,
forming a hardmask layer on the conductor for the first gate electrode,
removing a portion of the hardmask layer to expose a portion of the conductor for the first gate electrode,
removing an exposed portion of the conductor for the first gate electrode and exposing a portion of the gate dielectric layer,
supplying a reaction inhibitor onto an exposed portion of the gate dielectric layer and the hardmask layer to adsorb the reaction inhibitor onto the exposed portion of the gate dielectric layer and the hardmask layer,
supplying a reaction auxiliary agent, which reacts with the reaction inhibitor, to selectively remove the reaction inhibitor adsorbed on the exposed portion of the gate dielectric layer,
supplying a reaction precursor for a second gate electrode to adsorb the reaction precursor for the second gate electrode on a portion of the gate dielectric layer from which the reaction inhibitor is removed,
supplying a reactant for the second gate electrode, which reacts with the reactant precursor for the second gate electrode, to selectively form the second gate electrode on the gate dielectric layer, and
removing the hardmask layer.

19. The method of claim 18, further comprising forming a conductive layer having a different work function from the second gate electrode after the removing of the hardmask layer.

20. The method of claim 18, wherein
the gate dielectric layer comprises an oxide including Ag, Mg, Cu, Zr, Zn, Hf, Cr, Al, Co, Fe, Ti, Sn, or a combination thereof or an oxynitride including Ag, Mg, Cu, Zr, Zn, Hf, Cr, Al, Co, Fe, Ti, Sn, or a combination thereof,
the hardmask layer comprises an oxide including Si, Ge, Mn, W, Mo, or a combination thereof or an oxynitride including Si, Ge, Mn, W, Mo, or a combination thereof.
